(19) United States
(12) Patent Application Publication
(10) Pub. No.: US 2016/0172167 A1
(43) Pub. Date: Jun. 16, 2016

(54) COPPER MATERIAL FOR HIGH-PURITY COPPER SPUTTERING TARGET, AND HIGH-PURITY COPPER SPUTTERING TARGET

(71) Applicant: MITSUBISHI MATERIALS CORPORATION, Tokyo (JP)

(72) Inventors: Akira SAKURAI, Osaka (JP); Yu GU, Iwaki-shi (JP); Yuji SATO, Iwaki-shi (JP); Satoshi KUMAGAI, Osaka (JP)

(21) Appl. No.: 14/902,671

(22) PCT Filed: Jul. 8, 2014
(86) PCT No.: PCT/JP2014/068198

§ 371 Date: Jan. 4, 2016

(30) Foreign Application Priority Data
Jul. 11, 2013 (JP) 2013-145733
Jun. 4, 2014 (JP) 2014-116011

(51) Int. Cl. H01J 37/34; C23C 14/34; C22C 9/00

(52) U.S. Cl. CPC H01J 37/3426; C22C 9/00; C23C 14/3414; H01J 2237/081; H01J 2237/3323

(57) ABSTRACT

In a copper material for a high-purity copper sputtering target of the present invention, a purity of Cu excluding O, H, N, and C is in a range of 99.999980 mass % or higher and 99.999998 mass % or lower, an amount of Al is 0.005 ppm by mass or less, and an amount of Si is 0.05 ppm by mass or less.

### TECHNICAL FIELD

The present invention relates to a copper material for a high-purity copper sputtering target, and a high-purity copper sputtering target, which are used when an interconnection film (high-purity copper film) is formed in, for example, a semiconductor device, a flat panel display such as a liquid crystal or organic EL panel, and a touch panel.

Priority is claimed on Japanese Patent Application No. 2013-145733, filed Jul. 11, 2013 and Japanese Patent Application No. 2014-116011, filed Jun. 4, 2014, the contents of which are incorporated herein by reference.

### BACKGROUND ART

Hitherto, Al has been widely used for an interconnection film in a semiconductor device, a flat panel display such as a liquid crystal or organic EL panel, a touch panel, and the like. Recently, miniaturization (width reduction) and thinning of the interconnection film have been achieved, and thus an interconnection film having a lower specific resistance than that in the related art is required.

Therefore, due to the miniaturization and thinning of the interconnection film described above, an interconnection film made of copper (Cu), which is a material having a lower specific resistance than that of Al, is provided.

However, the above-mentioned interconnection film is typically formed by using a sputtering target in a vacuum atmosphere. Here, in a case where film formation is performed by using a sputtering target, an abnormal discharge (arcing) may be generated due to foreign matter in the sputtering target, and thus a uniform interconnection film may not be formed. The abnormal discharge is a phenomenon in which an excessively higher current than that during normal sputtering suddenly and drastically flows and an abnormally high discharge is rapidly generated. When such an abnormal discharge is generated, there is concern that particles may be generated or the film thickness of the interconnection film may become non-uniform. Therefore, it is preferable for the abnormal discharge to be avoided during film formation as much as possible.

Here, in PTL 1, a sputtering target made of high-purity copper having a purity of 6N or higher is suggested. In the high-purity copper sputtering target described in PTL 1, the amount of each of P, S, O, and C is 1 ppm or less, and non-metallic inclusions having a particle size of 0.5 μm to 20 μm are in a proportion of 30,000 pieces/g or lower, thereby reducing foreign matter in the sputtering target and suppressing an abnormal discharge (arcing) and particles.

### CITATION LIST

### Patent Literature

[PTL 1] Japanese Patent No. 4680325

### SUMMARY OF INVENTION

### Technical Problem

Recently, a further increase in the density of an interconnection film has been required for a semiconductor device, a flat panel display such as a liquid crystal or organic EL panel, a touch panel, and the like. Therefore, an interconnection film which is further miniaturized and thinned than in the related art needs to be stably formed.

In the high-purity copper described in PTL 1, as described above, the amount of P, S, O, and C is limited to a purity of about 6N, and the number of non-metallic inclusions is limited. However, this is insufficient for a reduction in foreign matter, and there is concern that an abnormal discharge (arcing) may be generated during film formation. Therefore, a miniaturized and thinned interconnection film cannot be stably formed.

In addition, in order to reduce foreign matter in a sputtering target, using 8N copper having a further improved purity of 99.999999 mass % or higher, may be considered. However, in a case where a copper material having this purity is produced, a refining process needs to be repeated three or more times, and thus there is a problem in that production costs are significantly increased.

The invention has been made taking the foregoing circumstances into consideration, and an object thereof is to provide a copper material for a high-purity copper sputtering target, which can suppress the generation of an abnormal discharge and enable stable film formation, and can be produced at a low cost, and a high-purity copper sputtering target made of the copper material for a high-purity copper sputtering target.

### Solution to Problem

In order to solve the problems, in a copper material for a high-purity copper sputtering target of the present invention, a purity of Cu excluding O (oxygen), H (hydrogen), N (nitrogen), and C (carbon) is in a range of 99.999980 mass % or higher and 99.999998 mass % or lower, an amount of Al (aluminum) is 0.005 ppm by mass or less, and an amount of Si (silicon) is 0.05 ppm by mass or less.

In the copper material for a high-purity copper sputtering target having this configuration, since the purity of Cu excluding O, H, N, and C is in a range of 99.999980 mass % (6N8) or higher and 99.999998 mass % (7N8) or lower, a refining process does not need to be performed three or more times, and production can be performed at a relatively low cost.

In addition, Al and Si are elements which easily form oxides, carbides, nitrides, and the like and thus are likely to remain as foreign matter in a sputtering target. Here, focusing on Al and Si among impurities, by limiting the amount of Al to 0.005 ppm by mass or less and limiting the amount of Si to 0.05 ppm by mass or less, it becomes possible to suppress the generation of an abnormal discharge (arcing) during film formation even when the purity of Cu is in a range of 99.999980 mass % or higher and 99.999998 mass % or lower. In addition, such foreign matter is not incorporated into the film, and a high-purity copper film having high quality can be formed.

Here, in the copper material for a high-purity copper sputtering target of the present invention, it is preferable that an amount of S is 0.03 ppm by mass or less.

In this case, since the amount of S is limited to 0.03 ppm by mass or less, foreign matter formed of sulfides can be prevented from remaining in the sputtering target. In addition, S can be prevented from being gasified and ionized during film formation and causing a decrease in the degree of vacuum. Accordingly, an abnormal discharge (arcing) can be suppressed, and thus a high-purity copper film can be stably formed.

In addition, in the copper material for a high-purity copper sputtering target of the present invention, it is preferable that an amount of Cl is 0.1 ppm by mass or less.

In this case, since the amount of Cl is limited to 0.1 ppm by mass or less, foreign matter formed of chlorides can be prevented from remaining in the sputtering target. In addition, Cl can be prevented from being gasified and ionized during film formation and causing a decrease in the degree of vacuum. Accordingly, an abnormal discharge (arcing) can be suppressed, and thus a high-purity copper film can be stably formed.

Furthermore, in the copper material for a high-purity copper sputtering target of the present invention, it is preferable that an amount of O is less than 1 ppm by mass, an amount of H is less than 1 ppm by mass, and an amount of N is less than 1 ppm by mass.

In this case, since the amount of each of the gas components O, H, and N is limited to less than 1 ppm by mass, a decrease in the degree of vacuum during film formation can be suppressed, and the generation of an abnormal discharge (arcing) can be suppressed. In addition, the generation of particles due to the abnormal discharge is suppressed, and thus a high-purity copper film having high quality can be formed.

In addition, in the copper material for a high-purity copper sputtering target of the present invention, it is preferable that an amount of C is 1 ppm by mass or less.

In this case, since the amount of C is limited to 1 ppm by mass or less, foreign matter formed of carbides or a carbon simple substance can be prevented from remaining in the sputtering target. Accordingly, an abnormal discharge (arcing) can be suppressed, and thus a high-purity copper film can be stably formed.

A high-purity copper sputtering target of the present invention is produced by using the copper material for a high-purity copper sputtering target.

According to the high-purity copper sputtering target having this configuration, since the purity of Cu excluding O, H, N, and C is in a range of 99.999980 mass % or higher and 99.999998 mass % or lower, the refining process does not need to be performed three or more times, and production can be performed at a relatively low cost. In addition, since the generation of foreign matter is suppressed, an abnormal discharge (arcing) is less likely to be generated during film formation, and a high-purity copper film can be stably formed. In addition, the incorporation of foreign matter into the film is suppressed, and a high-purity copper film having high quality can be formed.

### Advantageous Effects of Invention

According to the present invention, a copper material for a high-purity copper sputtering target, which can suppress the generation of an abnormal discharge and enable stable film formation, and can be produced at a low cost, and a high-purity copper sputtering target made of the copper material for a high-purity copper sputtering target can be provided.

### DESCRIPTION OF EMBODIMENTS

Hereinafter, a copper material for a high-purity copper sputtering target, and a high-purity copper sputtering target according to an embodiment of the present invention will be described.

The copper material for a high-purity copper sputtering target and the high-purity copper sputtering target in the embodiment are used when a high-purity copper film, which is used as an interconnection film in a semiconductor device, a flat panel display such as a liquid crystal or organic EL panel, and a touch panel, and the like, is formed on a substrate.

In addition, in the composition of the copper material for a high-purity copper sputtering target and the high-purity copper sputtering target in this embodiment, the purity of Cu excluding O, H, N, and C is in a range of 99.999980 mass % or higher and 99.999998 mass % or lower, the amount of Al is 0.005 ppm by mass or less, and the amount of Si is 0.05 ppm by mass or less.

In addition, in this embodiment, the amount of S is 0.03 ppm by mass or less, the amount of Cl is 0.1 ppm by mass or less, the amount of O is less than 1 ppm by mass, the amount of H is less than 1 ppm by mass, the amount of N is less than 1 ppm by mass, and the amount of C is 1 ppm by mass or less.

Hereinafter, the reason that the composition of the copper material for a high-purity copper sputtering target and the high-purity copper sputtering target in this embodiment is specified as described above will be described.

### (Cu: 99.999980 Mass % or Higher and 99.999998 Mass % or Lower)

In a case of forming an interconnection film (high-purity copper film) through sputtering, in order to suppress an abnormal discharge (arcing), it is preferable that impurities are reduced as much as possible. However, in order to highly purify copper to a purity of 99.999999 mass % (8N) or higher, a refining treatment needs to be performed three or more times, resulting in a significant increase in production costs. Here, in this embodiment, a reduction in production costs is achieved by allowing the purity of Cu obtained by the refining process, which is performed twice, to be 99.999980 mass % (6N8) or higher and 99.999998 mass % (7N8) or lower.

### (Al: 0.005 ppm by Mass or Less)

Al is an element which easily forms oxides, carbides, nitrides, and the like and is likely to remain as foreign matter in a sputtering target. Here, by limiting the amount of Al to 0.005 ppm by mass or less, it becomes possible to suppress the generation of an abnormal discharge (arcing) during film formation even when the purity of Cu is in a range of 99.999980 mass % or higher and 99.999998 mass % or lower. The detection limit of Al is 0.001 ppm by mass. The range of Al is preferably less than 0.001 ppm by mass.

### (Si: 0.05 ppm by Mass or Less)

Si is an element which easily forms oxides, carbides, nitrides, and the like and is likely to remain as foreign matter in a sputtering target. Here, by limiting the amount of Si to 0.05 ppm by mass or less, it becomes possible to suppress the generation of an abnormal discharge (arcing) during film formation even when the purity of Cu is in a range of 99.999980 mass % or higher and 99.999998 mass % or lower. In addition, the lower the amount of Si, the more preferable it is. However, an excessive reduction in Si causes an increase in costs. Therefore, the amount of Si may be 0.005 ppm by mass or higher. In addition, the amount of Si may also be 0.005 ppm by mass or higher and 0.05 ppm by mass or lower.

### (S: 0.03 ppm by Mass or Less)

S is an element which forms sulfides by reacting with other impurities and is likely to remain as foreign matter in a sputtering target. In addition, in a case where S is present as a simple substance, there is concern that S may be gasified and ionized during film formation and cause a decrease in the degree of vacuum and the occurrence of an abnormal discharge (arcing). For this reason, in this embodiment, the amount of S is limited to 0.03 ppm by mass or less. In addition, the lower the amount of S, the more preferable it is. However, an excessive reduction in S causes an increase in costs. Therefore, the amount of S may be 0.005 ppm by mass or higher. In addition, the amount of S is more preferably less than 0.01 ppm by mass.

### (Cl: 0.1 ppm by Mass or Less)

Cl is an element which forms chlorides by reacting with other impurities and is likely to remain as foreign matter in a sputtering target. In addition, in a case where Cl is present as a simple substance, there is concern that Cl may be gasified and ionized during film formation and cause a decrease in the degree of vacuum and the occurrence of an abnormal discharge (arcing). For this reason, in this embodiment, the amount of Cl is limited to 0.1 ppm by mass or less. In addition, the lower the amount of Cl, the more preferable it is. However, an excessive reduction in Cl causes an increase in costs. Therefore, the amount of Cl may be 0.005 ppm by mass or higher. In addition, the amount of Cl is more preferably less than 0.01 ppm by mass.

(O, H, and N: each Less than 1 ppm by Mass)

In a case where film formation is performed by using a sputtering target, the film formation is performed in a vacuum atmosphere. Therefore, when such gas components are present in high proportions in the target, there is concern that the degree of vacuum may be decreased during the film formation and an abnormal discharge (arcing) may be incurred. In addition, there is concern that particles may be generated due to the abnormal discharge, and the quality of a formed high-purity copper film may be deteriorated. For this reason, in this embodiment, the amount of each of O, H, and N is limited to less than 1 ppm by mass. In addition, the lower the amount of O, H, and N, the more preferable it is. However, an excessive reduction in O, H, and N causes an increase in costs. Therefore, the amount of each of O, H, and N may be 0.1 ppm by mass or higher. In addition, it is more preferable that the amount of O is less than 0.5 ppm by mass, and the amount of H is less than 0.2 ppm by mass.

### (C: 1 ppm by Mass or Less)

C is an element which forms carbides by reacting with other impurities and is likely to remain as foreign matter in a sputtering target. In addition, C is also likely to remain as a simple substance in the sputtering target. Therefore, there is concern that an abnormal discharge (arcing) may be incurred. For this reason, in this embodiment, the amount of C is limited to 1 ppm by mass or less.

Here, in this embodiment, the amount of each of Au, Pd, and Pb is further limited to 0.05 ppm by mass or less.

The elements Au, Pd, and Pb are elements having higher sputtering rates than that of Cu. The sputtering rate represents the number of atoms sputtered by the incidence of a single ion. For example, in a case where Ar sputtering is performed with an ionization energy of 500 eV, the sputtering rate of Au is 2.5 atoms/ion, the sputtering rate of Pd is 2.08 atoms/ion, and the sputtering rate of Pb is 2.7 atoms/ion, while the sputtering rate of Cu is 2.0 atoms/ion. Such elements having higher sputtering rates than that of Cu are sputtered prior to Cu during film formation, and there is concern that the elements may be incorporated into the film. In addition, the elements Au, Pd, and Pb have higher resistance values than that of Cu, and thus there is concern that the resistance value of a high-purity copper film (interconnection film) may be increased when the elements are incorporated into the film.

For this reason, in this embodiment, the amount of each of the elements Au, Pd, and Pb is limited to 0.05 ppm by mass or less. Since the detection limits of Au, Pd, and Pb are respectively 0.01 ppm by mass, 0.005 ppm by mass, and 0.001 ppm, in a case where Au, Pd, and Pb can be detected, the ranges thereof may be respectively 0.01 to 0.05 ppm by mass, 0.005 to 0.05 ppm by mass, and 0.001 to 0.05 ppm by mass.

In addition, in this embodiment, the amount of each of Cr, Fe, Co, Ni, Ge, and Pt is further limited to 0.05 ppm by mass or less.

The elements Cr, Fe, Co, Ni, Ge, and Pt are elements having high sputtering rates although being lower than that of Cu, and thus there is concern that the elements may be incorporated into the film during film formation. For example, in a case where Ar sputtering is performed with an ionization energy of 500 eV, the sputtering rate of Cr is 1.18 atoms/ion, the sputtering rate of Fe is 1.10 atoms/ion, the sputtering rate of Co is 1.22 atoms/ion, the sputtering rate of Ni is 1.45 atoms/ion, the sputtering rate of Ge is 1.1 atoms/ion, and the sputtering rate of Pt is 1.40 atoms/ion.

For this reason, in this embodiment, the amount of each of the elements Cr, Fe, Co, Ni, Ge, and Pt is limited to 0.05 ppm by mass or less. The detection limit of Fe, Co, and Ni is 0.001 ppm by mass, the detection limit of Cr is 0.002 ppm by mass, the detection limit of Ge is 0.005 ppm by mass, and the detection limit of Pt is 0.01 ppm by mass. Therefore, in a case where the elements can be detected, the ranges thereof may be respectively 0.001 to 0.05 ppm by mass, 0.002 to 0.05 ppm by mass, 0.005 to 0.05 ppm by mass, and 0.01 to 0.05 ppm by mass.

In addition, in this embodiment, the amount of each of Be, Ti, V, Zr, Nb, Mo, W, Th, and U is further limited to 0.05 ppm by mass or less.

The elements Be, Ti, V, Zr, Nb, Mo, W, Th, and U are elements having high sputtering rates although being lower than that of Cu, and thus there is concern that the elements may be incorporated into the film during film formation. For example, in a case where Ar sputtering is performed with an ionization energy of 500 eV, the sputtering rate of Be is 0.51 atoms/ion, the sputtering rate of Ti is 0.51 atoms/ion, the sputtering rate of V is 0.65 atoms/ion, the sputtering rate of Zr is 0.65 atoms/ion, the sputtering rate of Nb is 0.60 atoms/ion, the sputtering rate of Mo is 0.80 atoms/ion, the sputtering rate of W is 0.57 atoms/ion, the sputtering rate of Th is 0.62 atoms/ion, and the sputtering rate of U is 0.85 atoms/ion.

For this reason, in this embodiment, the amount of each of the elements Be, Ti, V, Zr, Nb, Mo, W, Th, and U is limited to 0.05 ppm by mass or less. The detection limits of Be, Ti, V, Zr, and W are 0.001 ppm by mass, the detection limit of Nb and Mo is 0.005 ppm by mass, and the detection limit of Th and U is 0.0001 ppm by mass. Therefore, in a case where the elements can be detected, the ranges thereof may be respectively 0.001 to 0.05 ppm by mass, 0.005 to 0.05 ppm by mass, and 0.0001 to 0.05 ppm by mass.

In addition, in this embodiment, as described above, the upper limit of the amount of each of various impurities is set. However, there is a need to regulate the sum of the amounts of the impurities so as to allow the purity of Cu excluding O, H, N, and C to be in a range of 99.999980 mass % or higher and 99.999998 mass % or lower.

Here, the analysis of the impurities excluding O, H, N, and C can be performed by using a glow-discharge mass spectrometer (GD-MS).

In addition, the analysis of O can be performed according to an inert gas fusion-infrared absorption method, the analysis of H and N can be performed according to an inert gas fusion-thermal conductivity method, and the analysis of C can be performed according to an infrared absorption method after combustion.

Next, a producing method of the copper material for a high-purity copper sputtering target and the high-purity copper sputtering target in this embodiment will be described.

First, an electrolytic copper having a copper purity of 99.99 mass % or higher is prepared and is subjected to electrolytic refining.

The above-mentioned electrolytic copper is used as the anode, a titanium plate is used as the cathode, and the anode and cathode are immersed into an electrolyte for electrolysis. Here, as the electrolyte, an electrolyte which is prepared by diluting copper nitrate as a reagent with water and further contains a hydrochloric acid added thereto is used. As described above, by adding the hydrochloric acid to the copper nitrate electrolyte, the generation of nitrous acid gas can be suppressed, and thus it becomes possible to reduce the amount of impurities in electrodeposited copper (refer to Japanese Patent No. 3102177). This electrolytic refining is repeated twice. Accordingly, high-purity copper in which the purity of Cu excluding O, H, N, and C is in a range of 99.999980 mass % or higher and 99.999998 mass % or lower is obtained.

In addition, in this embodiment, the amount of each of Al and Si of the anode (electrolytic copper) used in the electrolytic refining process is specified to 1 ppm by mass or less, and furthermore, the amount of each of Al and Si in the electrolyte is specified to 1 ppm by mass or less. In addition, the cleanliness of a room in which the electrolytic refining is performed is set to “class 10000” or lower in the United States Federal Standard 209E air cleanliness standards (ISO 7 or lower in IS014644-1). By allowing the electrolytic refining to be performed under these conditions, it becomes possible for the amounts of Al and Si to be 0.005 ppm by mass or less and 0.05 ppm by mass or less, respectively.

In the above-described manner, a copper material for a high-purity copper sputtering target in which the purity of Cu excluding O, H, N, and C is in a range of 99.999980 mass % or higher and 99.999998 mass % or lower, the amount of Al is 0.005 ppm by mass or less, and the amount of Si is 0.05 ppm by mass or less can be obtained.

Next, the copper material for a high-purity copper sputtering target is used as a melting raw material and is melted in a vacuum melting furnace, thereby producing a high-purity copper ingot. The high-purity copper ingot is subjected to hot working, cold working, and machining as necessary to be formed in a predetermined shape.

In the above-described manner, the high-purity copper sputtering target of this embodiment is produced.

According to the copper material for a high-purity copper sputtering target and the high-purity copper sputtering target in this embodiment configured as described above, since the purity of Cu excluding O, H, N, and C is in a range of 99.999980 mass % or higher and 99.999998 mass % or lower, the refining process does not need to be performed three or more times, and production can be performed at a relatively low cost.

In addition, since the amounts of Al and Si, which are elements that easily form oxides, carbides, nitrides, and the like and are likely to remain as foreign matter, are respectively limited to 0.005 ppm by mass or less and 0.05 ppm by mass or less, even when the purity of Cu is in a range of 99.999980 mass % or higher and 99.999998 mass % or lower, an abnormal discharge (arcing) caused by foreign matter can be suppressed, and thus a high-purity copper film (interconnection film) can be stably formed.

In addition, in this embodiment, since the amount of S is limited to 0.03 ppm by mass or less, sulfides can be prevented from remaining in the sputtering target as foreign matter, and S can be prevented from being gasified and ionized during film formation and causing a decrease in the degree of vacuum. Therefore, even when the purity of Cu is in a range of 99.999980 mass % or higher and 99.999998 mass % or lower, an abnormal discharge (arcing) can be reliably prevented during film formation.

Furthermore, in this embodiment, since the amount of Cl is limited to 0.1 ppm by mass or less, chlorides can be prevented from remaining in the sputtering target as foreign matter, and Cl can be prevented from being gasified and ionized during film formation and causing a decrease in the degree of vacuum. Therefore, even when the purity of Cu is in a range of 99.999980 mass % or higher and 99.999998 mass % or lower, an abnormal discharge (arcing) can be reliably prevented.

In addition, in this embodiment, since the amount of each of the gas components O, H, and N is limited to less than 1 ppm by mass, a decrease in the degree of vacuum during film formation can be suppressed, and the generation of an abnormal discharge (arcing) can be suppressed. Furthermore, the generation of particles due to the abnormal discharge is suppressed, and thus a high-purity copper film having high quality can be formed.

Furthermore, in this embodiment, since the amount of C is limited to 1 ppm by mass or less, foreign matter formed of carbides or a carbon simple substance can be prevented from remaining in the sputtering target. Therefore, even when the purity of Cu is in a range of 99.999980 mass % or higher and 99.999998 mass % or lower, an abnormal discharge (arcing) can be reliably prevented.

In addition, in this embodiment, since the amount of each of Au, Pd, and Pb, which are elements having higher sputtering rates than that of Cu and high resistance values is limited to 0.05 ppm by mass or less, the incorporation of the elements Au, Pd, and Pb into the film during film formation can be suppressed, and an increase in the resistance value of the high-purity copper film (interconnection film) can be suppressed.

Furthermore, in the embodiment, since the amount of each of Cr, Fe, Co, Ni, Ge, and Pt, which are elements having high sputtering rates although being lower than that of Cu is limited to 0.05 ppm by mass or less, the deterioration of the characteristics of the high-purity copper film (interconnection film) due to the incorporation of the elements Cr, Fe, Co, Ni, Ge, and Pt into the film can be prevented.

In addition, in the embodiment, since the amount of each of Be, Ti, V, Zr, Nb, Mo, W, Th, and U, which are elements having high sputtering rates although being lower than that of Cu is limited to 0.05 ppm by mass or less, the deterioration of the characteristics of the high-purity copper film (interconnection film) due to the incorporation of the elements Be, Ti, V, Zr, Nb, Mo, W, Th, and U into the film can be prevented.

While the embodiment of the present invention has been described above, the present invention is not limited thereto, and can be appropriately modified without departing from the technical spirit of the invention.

In this embodiment, the sputtering target for forming a high-purity copper film as an interconnection film is exemplified. However, the sputtering target is not limited thereto, and can also be applied to a case where a high-purity copper film is used for other uses.

In addition, the producing method is not limited to the embodiment, and another producing method may also be employed for the production.

### EXAMPLES

Hereinafter, results of evaluation tests for evaluating the copper material for a high-purity copper sputtering target and the high-purity copper sputtering target in the embodiment described above will be described.

### Invention Examples 1 to 5

An electrolytic copper containing 1 ppm by mass or less of Al, 1 ppm by mass or less of Si, and 20 ppm by mass or less of other impurities (excluding O, H, N, and C) was used as the raw material, and was subjected to electrolytic refining repeated twice under the electrolytic refining conditions exemplified in the embodiment, thereby producing a copper raw material (copper material).

The raw material produced in the above-described producing method was put into a crucible made of high-purity carbon (carbon crucible) and was subjected to vacuum melting (a pressure of 10⁻⁵ Pa) at 1130° C. In addition, after the melting under a vacuum, the resultant was held at 1150° C. for 30 minutes. Thereafter, the melted raw material was poured into a mold made of high-purity carbon (carbon mold) in a vacuum state (a pressure of 10⁻⁵ Pa), thereby producing a high-purity copper ingot having a size of 200 mm in diameter×800 mm in height. The composition of the obtained ingot is shown in Table 1.

The produced high-purity copper ingot was forged at 500° C., the obtained high-purity forged ingot was cut to a size of 300 mm in diameter×15 mm in height, and the cut forged ingot was bonded to a Cr—Zr—Cu (UNS.C18150) backing plate through hot isostatic pressing (HIP).

### Conventional Example 1

An electrolytic copper containing 2 ppm by mass or less of Al, 3 ppm by mass or less of Si, and 20 ppm by mass or less of other impurities (excluding O, H, N, and C) was used as the raw material, and was subjected to electrolytic refining repeated twice using a copper nitrate electrolyte, thereby obtaining a copper raw material having a composition in which the amount of Al is 0.005 ppm by mass and the amount of Si is 0.06 ppm by mass.

The raw material produced in the above-described producing method was put into a carbon crucible, melted at 1130° C. in an Ar atmosphere, and held at 1150° C. for 30 minutes. Thereafter, the melted raw material was poured into a carbon mold in an Ar atmosphere, thereby producing a high-purity copper ingot having a size of 200 mm in diameter×800 mm in height. The composition of the obtained ingot is shown in Table 1.

The produced high-purity copper ingot was forged at 500° C., the obtained high-purity forged ingot was cut to a size of 300 mm in diameter×15 mm in height, and the cut forged ingot was bonded to a Cr—Zr—Cu (UNS.C18150) backing plate through HIP.

### Conventional Example 2

An electrolytic copper containing 1 ppm by mass of Al, 1 ppm by mass of Si, and 20 ppm by mass or less of other impurities (excluding O, H, N, and C) was used as the raw material, and was subjected to electrolytic refining using a copper nitrate electrolyte, thereby obtaining a copper raw material having a composition in which the amount of Al is 0.005 ppm by mass and the amount of Si is 0.06 ppm by mass.

The raw material produced in the above-described producing method was put into a carbon crucible, melted at 1130° C. in an Ar atmosphere, and held at 1150° C. for 30 minutes. Thereafter, the melted raw material was poured into a carbon mold in an Ar atmosphere, thereby producing a high-purity copper ingot having a size of 200 mm in diameter×800 mm in height. The composition of the obtained ingot is shown in Table 1.

The produced high-purity copper ingot was forged at 500° C., the obtained high-purity forged ingot was cut to a size of 300 mm in diameter×15 mm in height, and the cut forged ingot was bonded to a Cr—Zr—Cu (UNS.C18150) backing plate through HIP.

Here, the analysis of the impurities excluding O, H, N, and C was performed by using a glow-discharge mass spectrometer (VG-9000 manufactured by VG Elemental). The analysis order was based on the ASTM F1845-97 standards.

The analysis of O was performed according to an inert gas fusion-infrared absorption method (JIS H 1067:2002). Specifically, the analysis was performed by using TCEN600 manufactured by LECO Japan Corporation based on JIS Z 2613:1992. That is, a sample was heated by using a graphite crucible in an inert gas (argon or helium) stream and was fused (inert gas fusion). Next, carbon monoxide generated due to the fusion was introduced into an infrared detector, the amount of infrared light absorbed by the carbon monoxide was measured, and the amount of oxygen was calculated (infrared absorption method). The analysis of H was performed according to an inert gas fusion-thermal conductivity method. Specifically, the analysis was performed by using RHEN602 manufactured by LECO Japan Corporation based on JIS Z 2614:1990. That is, gas generated from the sample due to the inert gas fusion was captured in a fixed volume including a thermal conductivity cell, a change in thermal conductivity due to hydrogen was measured, and the amount of hydrogen was calculated.

The analysis of N was performed according to the inert gas fusion-thermal conductivity method like the analysis of H. Specifically, the analysis was performed by using TCEN600 manufactured by LECO Japan Corporation.

The analysis of C was performed according to an infrared absorption method after combustion. Specifically, the analysis was performed by using CSLS600 manufactured by LECO Japan Corporation based on JIS Z 2615:2009. That is, from combustion gas generated by burning the sample in an oxygen stream, water was removed, and the combustion gas was introduced into an infrared absorption cell. In addition, the amount of infrared light absorbed by carbon dioxide was measured, and the amount of carbon was calculated.

The analysis results of the impurities of the sputtering targets in Invention Examples 1 to 5 and Conventional Examples 1 and 2 are shown in Table 1.

TABLE 1

| | Impurities (ppm by mass) | | | | | | | | | | | | |
|---|---|---|---|---|---|---|---|---|---|---|---|---|---|
| | | | | | | | | | | | Be, Ti, V, | Total amount of | Copper |
| | | | | | | | | | Au, Pd, | Cr, Fe, Co, | Zr, Nb, Mo, | impurities excluding | purity |
| | Al | Si | S | Cl | O | H | N | C | Pb | Ni, Ge, Pt | W, Th, U | O, H, N, C | (mass %) |
| Invention | 0.003 | 0.032 | 0.012 | 0.03 | <0.5 | <0.2 | <1 | <1 | <0.05 | <0.05 | <0.05 | 0.12 | 99.999988 |
| Example 1 | | | | | | | | | | | | | |
| Invention | <0.001 | 0.011 | 0.021 | 0.01 | <0.5 | <0.2 | <1 | <1 | <0.05 | <0.05 | <0.05 | 0.07 | 99.999993 |
| Example 2 | | | | | | | | | | | | | |
| Invention | <0.001 | 0.003 | <0.01 | <0.01 | <0.5 | <0.2 | <1 | <1 | <0.05 | <0.05 | <0.05 | 0.02 | 99.999998 |
| Example 3 | | | | | | | | | | | | | |
| Invention | 0.005 | 0.025 | 0.011 | 0.03 | <0.5 | 0.9 | <1 | <1 | <0.05 | <0.05 | <0.05 | 0.1 | 99.999990 |
| Example 4 | | | | | | | | | | | | | |
| Invention | 0.001 | 0.05 | 0.016 | 0.02 | 1.2 | 0.5 | <1 | <1 | <0.05 | <0.05 | <0.05 | 0.09 | 99.999991 |
| Example 5 | | | | | | | | | | | | | |
| Conventional | 0.01 | 0.1 | 0.011 | 0.04 | <0.5 | <0.2 | <1 | <1 | <0.05 | 0.051 | 0.06 | 0.15 | 99.999985 |
| Example 1 | | | | | | | | | | | | | |
| Conventional | 0.002 | 0.02 | 0.1 | 0.3 | 3 | 0.7 | <1 | 1.3 | 0.1 | 0.184 | 0.08 | 0.8 | 99.999920 |
| Example 2 | | | | | | | | | | | | | |

### (Film Formation)

By using the sputtering targets of Invention Examples l to 5 and Conventional Examples 1 and 2, a copper thin film was formed on a wafer having a diameter of 200 mm (material: silicon). After the above-mentioned sputtering target was mounted in a sputtering apparatus, evacuation was performed to reach an arrival vacuum pressure of 10⁻⁵ Pa or less, pre-sputtering was performed by using ultra-high-purity Ar gas (purity: 5N) as the sputtering gas at a sputtering gas pressure of 0.3 Pa and a sputtering output of 0.5 kW supplied from a DC power supply, for 30 minutes, and thereafter sputtering was continuously performed for 5 hours at 1.5 kW.

### (Evaluations)

During the film formation, the number of particles (pieces/square inch) and the number of occurrences of arcing (times/target) were evaluated. The number of occurrences of arcing was measured by using an arcing counter embedded in the power supply. In addition, the number of particles that were present on the wafer and had a diameter of 0.3 μm or greater was measured by a particle counter. The evaluation results are shown in Table 2.

TABLE 2

| | | Number of |
|---|---|---|
| | Number of particles | occurrences of arcing |
| | (pieces/square inch) | (times/target) |
| Invention Example 1 | 2 | 0 |
| Invention Example 2 | 0 | 0 |
| Invention Example 3 | 0 | 0 |
| Invention Example 4 | 1 | 2 |
| Invention Example 5 | 2 | 4 |
| Conventional Example 1 | 34 | 8 |
| Conventional Example 2 | 80 | 20 |

In Conventional Example 2 in which the purity of copper deviated from the range of the embodiment of the present invention, the number of particles was as high as 80 pieces/square inch, and the number of occurrences of arcing was as high as 20 times/target. Accordingly, the high-purity copper film (interconnection film) could not be stably formed.

In Conventional Example 1, the number of particles was 34 pieces/square inch, and the number of occurrences of arcing was 8 times/target, which are lower than those of Conventional Example 2 but are still insufficient. It is estimated that this is because Al and Si, which are elements that form sulfides, carbides, nitrides, and the like, were contained in relatively high proportions of 0.01 ppm by mass and 0.1 ppm by mass, respectively.

Contrary to this, according to Invention Examples 1 to 5 in which the purity of Cu excluding O, H, N, and C was in a range of 99.999980 mass % or higher and 99.999998 mass % or lower, the amount of Al was 0.005 ppm by mass or less, and the amount of Si was 0.05 ppm by mass or less, the number of particles and the number of occurrences of arcing were significantly reduced to 2 pieces/square inch or lower and 4 times/target or lower, respectively.

From the above description, it was confirmed that according to Invention Examples 1 to 5, the generation of an abnormal discharge is suppressed and film formation can be stably performed.

### INDUSTRIAL APPLICABILITY

According to the copper material for a high-purity copper sputtering target and the high-purity copper sputtering target of the present invention, the generation of an abnormal discharge is suppressed and film formation can be stably performed. Therefore, an interconnection film which is miniaturized and thinned at a high density can be formed. In addition, the copper material for a high-purity copper sputtering target and the high-purity copper sputtering target of the present invention can be produced at a low cost, and thus are suitable for a semiconductor device, a flat panel display such as a liquid crystal or organic EL panel, a touch panel, and the like.

1. A copper material for a high-purity copper sputtering target,
wherein a purity of Cu excluding O, H, N, and C is in a range of 99.999980 mass % or higher and 99.999998 mass % or lower,
an amount of Al is 0.005 ppm by mass or less, and
an amount of Si is 0.05 ppm by mass or less.

2. The copper material for a high-purity copper sputtering target according to claim 1, wherein an amount of S is 0.03 ppm by mass or less.

3. The copper material for a high-purity copper sputtering target according to claim 1,
wherein an amount of Cl is 0.1 ppm by mass or less.

4. The copper material for a high-purity copper sputtering target according to claim 1,
wherein an amount of O is less than 1 ppm by mass,
an amount of H is less than 1 ppm by mass, and
an amount of N is less than 1 ppm by mass.

5. The copper material for a high-purity copper sputtering target according to claim 1,
wherein an amount of C is 1 ppm by mass or less.

6. A high-purity copper sputtering target produced by using the copper material for a high-purity copper sputtering target according to claim 1.

7. The copper material for a high-purity copper sputtering target according to claim 2,
wherein an amount of Cl is 0.1 ppm by mass or less.

8. The copper material for a high-purity copper sputtering target according to claim 2,
wherein an amount of O is less than 1 ppm by mass,
an amount of H is less than 1 ppm by mass, and
an amount of N is less than 1 ppm by mass.

9. The copper material for a high-purity copper sputtering target according to claim 3,
wherein an amount of O is less than 1 ppm by mass,
an amount of H is less than 1 ppm by mass, and
an amount of N is less than 1 ppm by mass.

10. The copper material for a high-purity copper sputtering target according to claim 7,
wherein an amount of O is less than 1 ppm by mass,
an amount of H is less than 1 ppm by mass, and
an amount of N is less than 1 ppm by mass.

11. The copper material for a high-purity copper sputtering target according to claim 2,
wherein an amount of C is 1 ppm by mass or less.

12. The copper material for a high-purity copper sputtering target according to claim 3,
wherein an amount of C is 1 ppm by mass or less.

13. The copper material for a high-purity copper sputtering target according to claim 4,
wherein an amount of C is 1 ppm by mass or less.

14. The copper material for a high-purity copper sputtering target according to claim 7,
wherein an amount of C is 1 ppm by mass or less.

15. The copper material for a high-purity copper sputtering target according to claim 8,
wherein an amount of C is 1 ppm by mass or less.

16. The copper material for a high-purity copper sputtering target according to claim 9,
wherein an amount of C is 1 ppm by mass or less.

17. A high-purity copper sputtering target produced by using the copper material for a high-purity copper sputtering target according to claim 2.

18. A high-purity copper sputtering target produced by using the copper material for a high-purity copper sputtering target according to claim 3.

19. A high-purity copper sputtering target produced by using the copper material for a high-purity copper sputtering target according to claim 4.

20. A high-purity copper sputtering target produced by using the copper material for a high-purity copper sputtering target according to claim 5.
